(19) United States
(12) Patent Application Publication
(10) Pub. No.: US 2026/0173812 A1
(43) Pub. Date: Jun. 18, 2026

(54) SHEET FIXING METHOD

(71) Applicant: DISCO CORPORATION, Tokyo (JP)

(72) Inventor: Yoshinobu Saito, Tokyo (JP)

(21) Appl. No.: 19/374,620

(22) Filed: Oct. 30, 2025

(30) Foreign Application Priority Data
Dec. 18, 2024 (JP) 2024-221486

(51) Int. Cl. H10P 72/70; H10P 54/00

(52) U.S. Cl. CPC H10P 72/7402; H10P 54/00

(57) ABSTRACT

A sheet fixing method for fixing a sheet to one surface of an adherend includes forming an adherend unit by fixing the sheet to the one surface of the adherend, after forming the adherend unit, supporting the adherend unit on a table such that another surface of the adherend on a side opposite to the one surface is exposed, after forming the adherend unit, covering at least the adherend in the adherend unit with a cover member, and after supporting the adherend unit on the table and covering the adherend with the cover member, making a pressure in an internal space of the cover member that covers the adherend higher than a pressure in a space outside the cover member.

### BACKGROUND OF THE INVENTION

### Field of the Invention

The present invention relates to a sheet fixing method for fixing a sheet to one surface of an adherend, a chip manufacturing method for dividing the adherend into a plurality of chips after the sheet is fixed to the one surface of the adherend, and a pressing apparatus that presses the adherend against the sheet to fix the sheet to the one surface of the adherend.

### Description of the Related Art

There is known a processing apparatus that attaches a sheet such as a tape to a front surface of a workpiece such as a semiconductor device wafer, holds the workpiece on a holding table under suction through the sheet, and then processes the workpiece by use of a processing unit such as a cutting unit or a laser beam irradiation unit with a back surface of the workpiece exposed upward (refer to Japanese Patent Laid-open No. 2010-087141 and Japanese Patent Laid-open No. 2010-082644, for example).

A plurality of planned dividing lines are usually set in a lattice manner on the front surface of the workpiece, and a device such as an integrated circuit (IC) is formed in each rectangular region marked out by the planned dividing lines. Test element groups (TEGs) may be formed on the planned dividing lines.

Since the front surface of the workpiece has minute irregularities formed due to the devices, the TEGs, and the like, when the sheet is attached to the front surface of the workpiece, minute gaps are often formed between the front surface of the workpiece and the sheet.

If the workpiece is divided in units of device by use of the processing apparatus described above with the minute gaps formed between the front surface of the workpiece and the sheet, there arises a problem that the minute gaps cause cracks, chipping, and the like, thereby damaging device chips.

### SUMMARY OF THE INVENTION

The present invention has been made in view of such a problem, and it is an object of the present invention to reduce the minute gaps between the front surface of the workpiece and the sheet.

In accordance with a first aspect of the present invention, there is provided a sheet fixing method for fixing a sheet to one surface of an adherend, the method including forming an adherend unit by fixing the sheet to the one surface of the adherend, after forming the adherend unit, supporting the adherend unit on a table such that another surface of the adherend on a side opposite to the one surface is exposed, after forming the adherend unit, covering at least the adherend in the adherend unit with a cover member, and after supporting the adherend unit on the table and covering the adherend with the cover member, making a pressure in an internal space of the cover member that covers the adherend higher than a pressure in a space outside the cover member.

Preferably, in making the pressure in the internal space of the cover member higher than the pressure in the space outside the cover member, gas is supplied to the internal space of the cover member, and the gas presses the adherend against the sheet.

Further, preferably, the sheet is a thermocompression bonding sheet having a base layer and not having an adhesive layer made of an adhesive, and, in forming the adherend unit, the base layer is heated to thermocompression-bond the thermocompression bonding sheet to the one surface of the adherend.

Further, preferably, in making the pressure in the internal space of the cover member higher than the pressure in the space outside the cover member, the pressure in the internal space of the cover member is made higher than the pressure in the space outside the cover member in a state in which the sheet fixed to the adherend of the adherend unit is heated.

Further, preferably, in making the pressure in the internal space of the cover member higher than the pressure in the space outside the cover member, the pressure in the internal space of the cover member is made higher than the pressure in the space outside the cover member in a state in which the sheet is held on the table under suction.

Further, preferably, in forming the adherend unit, the adherend unit is formed by fixing the sheet to an annular frame having an opening at a radially central portion thereof and to the one surface of the adherend and then integrating the adherend, the frame, and the sheet with one another with the adherend disposed in the opening.

In accordance with a second aspect of the present invention, there is provided a chip manufacturing method for fixing a sheet to one surface of an adherend and then dividing the adherend into a plurality of chips, the method including forming an adherend unit by fixing the sheet to the one surface of the adherend, after forming the adherend unit, supporting the adherend unit on a table such that another surface of the adherend on a side opposite to the one surface is exposed, after forming the adherend unit, covering at least the adherend in the adherend unit with a cover member, after supporting the adherend unit on the table and covering the adherend with the cover member, making a pressure in an internal space of the cover member that covers the adherend higher than a pressure in a space outside the cover member, and after making the pressure in the internal space of the cover member higher than the pressure in the space outside the cover member, dividing the adherend fixed to the sheet into a plurality of chips.

In accordance with a third aspect of the present invention, there is provided a pressing apparatus that presses an adherend against a sheet to fix the sheet to one surface of the adherend, the apparatus including a table for supporting an adherend unit obtained by fixing the sheet to the one surface of the adherend, such that another surface of the adherend on a side opposite to the one surface is exposed, and a cover member that is provided above the table and covers at least the adherend in the adherend unit supported on the table, in which the adherend is pressed against the sheet by making a pressure in an internal space of the cover member higher than a pressure in a space outside the cover member in a state in which the cover member covers at least the adherend.

In the sheet fixing method according to the first aspect of the present invention and the chip manufacturing method according to the second aspect of the present invention, after the sheet is fixed to the one surface of the adherend to form the adherend unit, the pressure in the internal space of the cover member that covers the adherend is made higher than the pressure in the space outside the cover member. This can reduce minute gaps existing between the one surface of the adherend and the sheet.

The pressing apparatus according to the third aspect of the present invention includes the support table and the cover member. In the pressing apparatus, in the state in which the cover member covers at least the adherend, the pressure in the internal space of the cover member is made higher than the pressure in the space outside the cover member, so that the adherend is pressed against the sheet. This can reduce minute gaps existing between the one surface of the adherend and the sheet.

The above and other objects, features and advantages of the present invention and the manner of realizing them will become more apparent, and the invention itself will best be understood from a study of the following description and appended claims with reference to the attached drawings showing preferred embodiments of the invention.

### BRIEF DESCRIPTION OF THE DRAWINGS

FIG. 1 is a flowchart of a sheet fixing method according to a first embodiment;

FIG. 2A is a perspective view of a workpiece;

FIG. 2B is a perspective view of a frame unit;

FIG. 3 is a schematic view of an attachment apparatus including a pressing apparatus;

FIG. 4A is a side view illustrating, partially in cross section, how a sheet is attached to a frame;

FIG. 4B is a side view illustrating, partially in cross section, how the sheet is cut out;

FIG. 4C is a sectional view of the frame unit;

FIG. 5A is a side view of a sheet fixing apparatus, partially illustrated in cross section;

FIG. 5B is a side view illustrating, partially in cross section, how a workpiece unit is formed;

FIG. 6A is a side view of the workpiece unit, partially illustrated in cross section;

FIG. 6B is a perspective view of the workpiece unit;

FIG. 7 is a side view illustrating, partially in cross section, that the workpiece unit is supported on a second chuck table;

FIG. 8A is a side view of the pressing apparatus, partially illustrated in cross section;

FIG. 8B is a side view illustrating, partially in cross section, that at least the workpiece is covered with a chamber;

FIG. 9 is a side view illustrating, partially in cross section, how the pressure in an internal space of the chamber is made higher than the pressure in a space outside the chamber;

FIG. 10 is a flowchart of a chip manufacturing method according to a second embodiment;

FIG. 11A is a side view illustrating, partially in cross section, how the workpiece is divided into a plurality of device chips; and

FIG. 11B is a perspective view of one device chip.

### DETAILED DESCRIPTION OF THE PREFERRED EMBODIMENTS

### First Embodiment

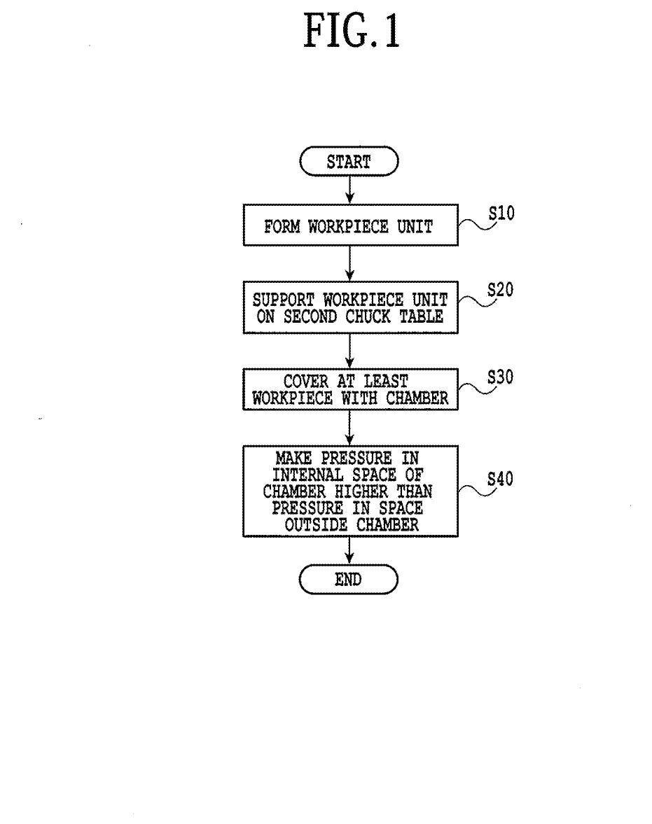

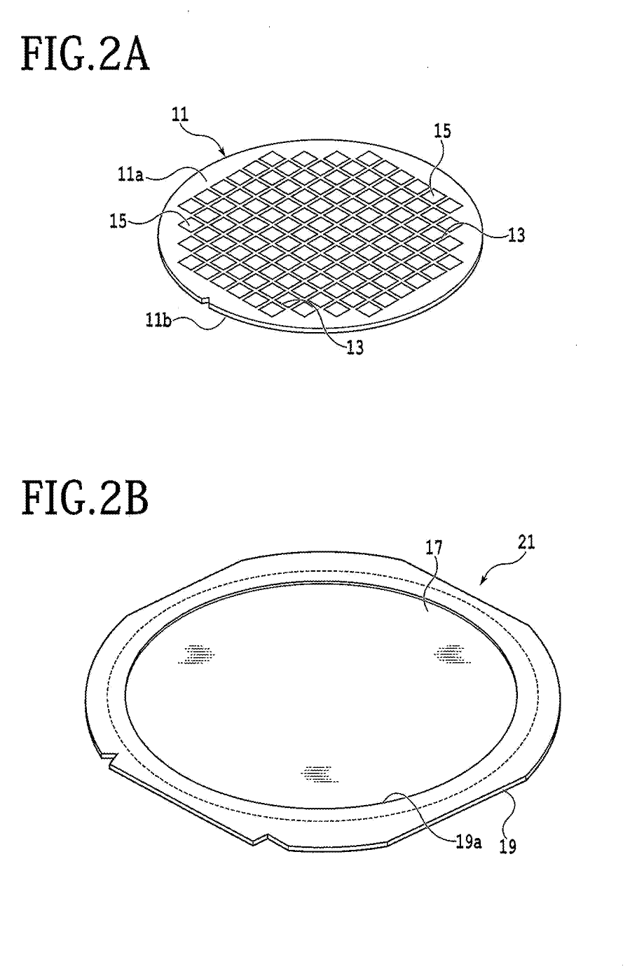

An embodiment according to one aspect of the present invention is described with reference to the attached drawings. FIG. 1 is a flowchart of a sheet fixing method according to a first embodiment. In the present embodiment, steps are performed in the order of S10, S20, S30, and S40, so that a sheet 17 illustrated in FIG. 2B is fixed to a workpiece (i.e., adherend) 11 illustrated in FIG. 2A.

However, the sheet fixing method is not necessarily limited to the one performed in the order from S10-S40. While S30 is performed after S20 in the case described in the present embodiment, S20 may be performed after S30 as will be described later in detail.

First, the workpiece 11, the sheet 17, and a frame 19 are described. FIG. 2A is a perspective view of the workpiece 11. The workpiece 11 is in the shape of a disk (i.e., in a plate shape having circular front and back surfaces) and includes a disk-shaped semiconductor wafer made of silicon (Si), silicon carbide (SiC), gallium nitride (GaN), or the like.

The workpiece 11 has a front surface (i.e., one surface) 11a and a back surface (i.e., the other surface) 11b, both of the surfaces being circular. The back surface 11b is positioned on the side opposite to the front surface 11a. A plurality of planned dividing lines 13 are set in a lattice manner on the front surface 11a.

A device 15 such as an IC is formed in each of a plurality of regions marked out by the plurality of planned dividing lines 13. The planned dividing lines 13 each have a predetermined width in a direction orthogonal to its longitudinal direction. The TEG (not illustrated) described above may be provided on one or a plurality of the planned dividing lines 13.

On the entire back surface 11b of the workpiece 11, a metal film (not illustrated) made of metal such as copper (Cu), aluminum (Al), or tungsten (W) is provided. That is, an entire back surface of the semiconductor wafer is coated with the metal film.

It is to be noted that coating the entire back surface 11b of the workpiece 11 with the metal film is optional. In a case in which the back surface 11b is not coated with the metal film, the back surface of the semiconductor wafer is exposed as the back surface 11b of the workpiece 11.

FIG. 2B is a perspective view of a frame unit 21 formed by integrating the sheet 17 in a circular shape with the frame 19 in an annular shape. The sheet 17 in the present embodiment is made of thermoplastic resin.

Examples of the thermoplastic resin include (i) polyolefin (PO) such as polyethylene (PE) and polypropylene (PP), (ii) polystyrene (PS), or (iii) polyester (PEs) such as polyethylene terephthalate (PET) and polyethylene naphthalate (PEN).

The sheet 17 in the present embodiment has a single-layer structure made of any of the materials described above. In addition, the sheet 17 does not have an adhesive layer including an adhesive but includes a base layer only. It is to be noted that the adhesive layer including an adhesive in the present embodiment means that it adheres to an object, without using water, heat, or the like, by only being applied with a slight pressure in a short period of time under an environment of ambient temperature and atmospheric pressure.

The present embodiment is advantageous in that, since the sheet 17 not having the adhesive layer but having the base layer only is used, none of the adhesive layer is left as a residue on the front surface 11a after the front surface 11a is separated from the sheet 17.

It is to be noted that the sheet 17 is not limited to the single-layer structure and may have a multilayer structure. For example, the sheet 17 may have two laminated layers including a relatively thick polyolefin layer and a relatively thin polyester layer. In this case, the polyolefin layer, which is relatively soft, is fixed to the workpiece 11.

In the case in which the sheet 17 has the single-layer structure, the sheet 17 has a thickness of 50 μm to 200 μm, for example. In the case in which the sheet 17 has the laminated structure, the sheet 17 has a polyolefin layer of 100 μm to 150 μm thickness and a polyester layer of 10 μm to 50 μm thickness, for example.

The sheet 17 is a thermocompression bonding sheet. When the sheet 17 is to be fixed to the workpiece 11, it is heated to reach a predetermined temperature to be softened. The temperature at which the sheet 17 is softened depends on the material. In the case of the sheet 17 with a single-layer structure made of polyethylene (i.e., in the case of a polyethylene sheet), the predetermined temperature at which the sheet 17 is softened is in the range of 120° C. to 140° C.

Further, in the case of the sheet 17 with a single-layer structure made of polypropylene (i.e., in the case of a polypropylene sheet), the predetermined temperature at which the sheet 17 is softened is in the range of 160° C. to 180° C. In the case of the sheet 17 with a single-layer structure made of polystyrene (i.e., in the case of a polystyrene sheet), the predetermined temperature at which the sheet 17 is softened is in the range of 220° C. to 240° C.

In the case of the sheet 17 with a single-layer structure made of polyethylene terephthalate (i.e., in the case of a polyethylene terephthalate sheet), the predetermined temperature at which the sheet 17 is softened is in the range of 250° C. to 270° C.

In the case of the sheet 17 with a single-layer structure made of polyethylene naphthalate (i.e., in the case of a polyethylene naphthalate sheet), the predetermined temperature at which the sheet 17 is softened is in the range of 160° C. to 180° C.

The sheet 17 has its outer peripheral portion fixed to the frame 19. The frame 19 is annular and is made of metal such as stainless steel. The frame 19 has a circular opening 19a at a radially central portion thereof. The opening 19a has a diameter larger than an outer diameter of the workpiece 11.

The outer peripheral portion of the sheet 17 described above is attached by thermocompression bonding to the frame 19 in a manner closing the opening 19a. That is, an outer diameter of the sheet 17 is larger than the diameter of the opening 19a but smaller than an outer diameter of the frame 19.

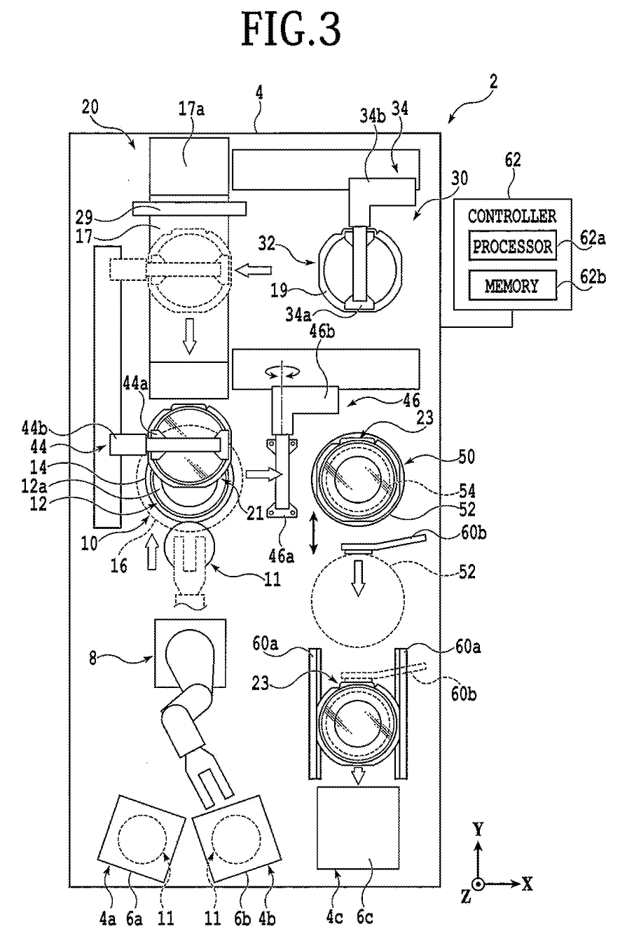

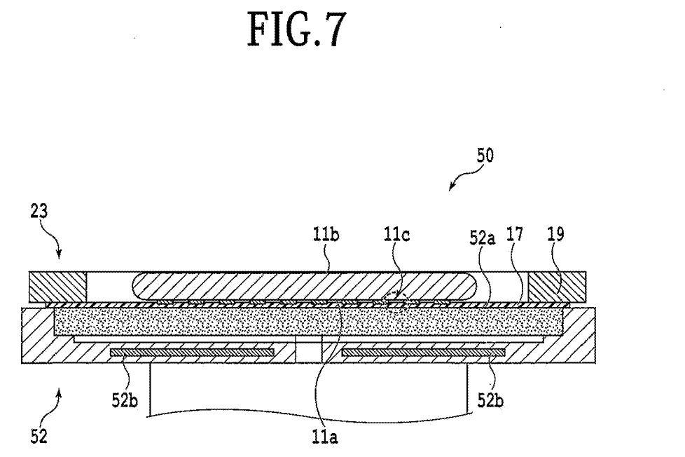

The workpiece 11 is subjected to thermocompression bonding at a sheet fixing apparatus 10 included in an attachment apparatus 2 (refer to FIG. 3), to be integrated with the frame 19 and the sheet 17 such that the front surface 11a of the workpiece 11 is in contact with the sheet 17, and thereafter further subjected to processing of reducing a minute gap 11c (refer to FIG. 7) existing between the front surface 11a and the sheet 17 at a pressing apparatus 50 included in the attachment apparatus 2.

Here, the attachment apparatus 2 is described with reference to FIG. 3. FIG. 3 is a schematic view of the attachment apparatus 2. In FIG. 3, some components of the attachment apparatus 2 are illustrated as functional blocks. X-axis directions (left-right directions), Y-axis directions (front-rear directions), and Z-axis directions (up-down directions) indicated in FIG. 3 are orthogonal to one another.

The attachment apparatus 2 has a base 4 that is in a rectangular parallelepiped shape and supports the components of the attachment apparatus 2. A pair of cassette placement areas 4a and 4b are provided at a corner portion of an upper surface of the base 4. A cassette 6a is placed in the cassette placement area 4a, and similarly, a cassette 6b is placed in the cassette placement area 4b. The cassettes 6a and 6b each house a plurality of workpieces 11 therein.

On the rear side of the cassette placement areas 4a and 4b (i.e., on one side of the Y-axis directions), a horizontal articulated transfer robot 8 is provided. The transfer robot 8 holds one workpiece 11 under suction with its end effector caused to enter the cassette 6a or the cassette 6b and then transfers the workpiece 11 to the sheet fixing apparatus 10 provided on the rear side of the transfer robot 8.

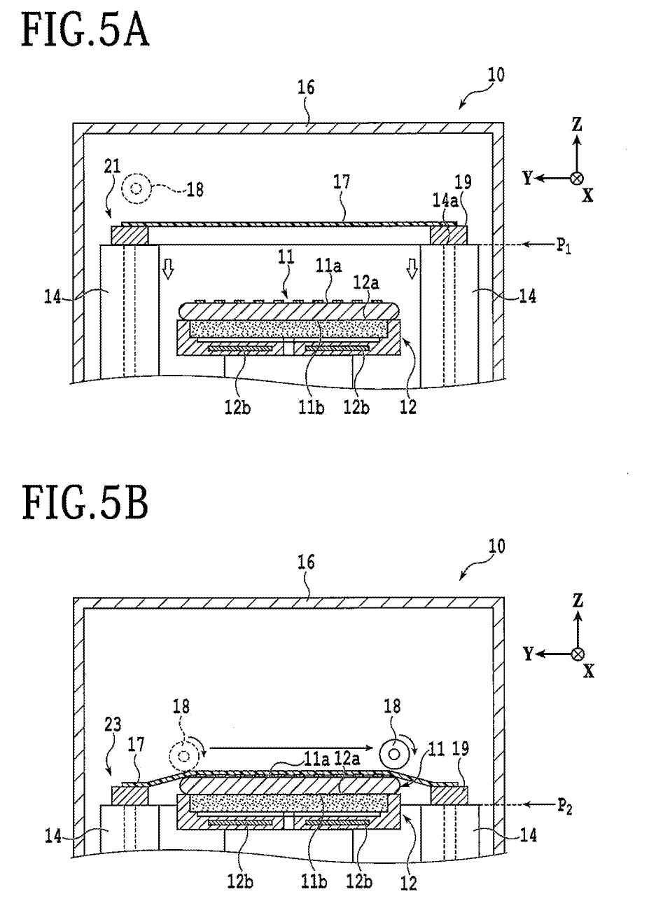

Here, the sheet fixing apparatus 10 is described with reference to FIGS. 5A and 5B. The sheet fixing apparatus 10 has a disk-shaped first chuck table 12, and the workpiece 11 transferred by the transfer robot 8 is placed on the first chuck table 12.

The first chuck table 12 has a disk-shaped frame body made of metal such as stainless steel. At a radially central portion of the frame body, a disk-shaped recessed portion is provided concentrically. In the recessed portion, a disk-shaped porous plate made of porous ceramic is fixed.

Upper surfaces of the frame body and the porous plate are substantially flush with each other and constitute a holding surface 12a that is substantially flat. A suction source (not illustrated) such as a vacuum pump is connected to the frame body, and negative pressure can be transmitted from the suction source to the upper surface of the porous plate.

Heat generators 12b as represented by cartridge heaters are provided in the frame body of the first chuck table 12. Heat generated by the heat generators 12b is transmitted from the holding surface 12a to the sheet 17 through the workpiece 11 and softens the sheet 17 at the time of thermocompression bonding.

It is to be noted that, while the first chuck table 12 in the present embodiment holds the workpiece 11 under suction with the negative pressure transmitted to the holding surface 12a, the first chuck table 12 may be an electrostatic chuck that sucks the workpiece 11 by use of electrostatic force or the like.

A cylindrical frame support base 14 is provided to surround the first chuck table 12. On an upper surface of the frame support base 14, a plurality of suction ports 14a are provided at substantially equal intervals along a circumferential direction of the frame support base 14. A suction source (not illustrated) such as a vacuum pump is connected to the frame support base 14, and negative pressure can be transmitted from the suction source to each suction port 14a.

The frame support base 14 in the present embodiment is movable along the Z-axis directions between a high position P₁ at which to receive the frame unit 21 and a low position P₂ at which the sheet 17 is attached to the workpiece 11, by an unillustrated actuator (a ball screw including a screw shaft coupled to a motor, or an air cylinder, for example).

Alternatively, it is possible that the first chuck table 12 is movable along the Z-axis directions, and it is also possible that the first chuck table 12 and the frame support base 14 are both movable along the Z-axis directions. That is, it is sufficient if the first chuck table 12 and the frame support base 14 are movable relative to each other along the Z-axis directions.

Further, the frame support base 14 may have a claw portion for sandwiching and fixing the frame 19 between the claw portion and the upper surface of the frame support base 14, instead of or in addition to using the negative pressure supplied through the plurality of suction ports 14a.

In the vicinity (on the upper side, for example) of the first chuck table 12, a cylindrical chamber 16 of a size large enough to cover the first chuck table 12 and the frame support base 14 is provided. (It is to be noted that FIG. 3 illustrates a rough position of the chamber 16 by a broken line.)

The chamber 16 is movable along the Z-axis directions by an unillustrated actuator (a ball screw including a screw shaft coupled to a motor, or an air cylinder, for example). The workpiece 11 and the frame unit 21 are transferred to the first chuck table 12 and the frame support base 14 when the chamber 16 is at an upper position.

After the workpiece 11 and the frame unit 21 are transferred, the chamber 16 moves downward to cover the first chuck table 12, the frame support base 14, and the like and define an enclosed space in cooperation with a bearer (not illustrated) positioned below the chamber 16.

A suction source (not illustrated) such as a vacuum pump is connected to the chamber 16 via a pipe portion (not illustrated). A solenoid valve (not illustrated) is provided to the pipe portion. In the present embodiment, when the solenoid valve is opened with the suction source actuated, the internal space of the chamber 16 is evacuated (medium vacuum of 10⁻¹ Pa to 10² Pa or low vacuum of 10² Pa to 10⁵ Pa, for example).

Above the holding surface 12a, there is provided a columnar pressure roller 18 whose longitudinal portion is arranged along the X-axis directions. It is to be noted that the pressure roller 18 is omitted from the illustration of FIG. 3. The pressure roller 18 is movable along the Z-axis directions and also movable along the Y-axis directions.

The length of the longitudinal portion of the pressure roller 18 in the X-axis directions is larger than the outer diameter of the frame 19. The pressure roller 18 is movable along the Y-axis directions while rotating and pressing the sheet 17 toward the frame 19.

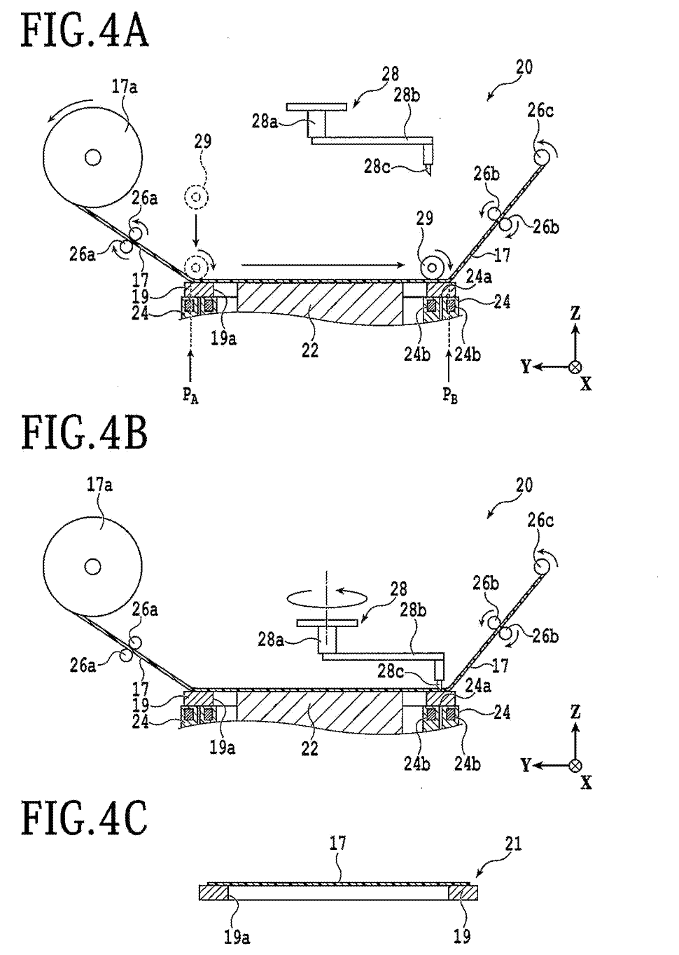

The frame unit 21 used in the sheet fixing apparatus 10 is formed by a frame unit forming apparatus 20 provided on the rear side of the first chuck table 12. Here, the frame unit forming apparatus 20 is described with reference to FIG. 4A.

The frame unit forming apparatus 20 has a columnar sheet support base 22. The sheet support base 22 is a metallic base having a substantially flat upper surface. A cylindrical frame support base 24 is provided to concentrically surround the sheet support base 22 and be separated from the sheet support base 22.

In the Z-axis directions, an upper surface of the frame support base 24 is positioned lower than the upper surface of the sheet support base 22 by an amount corresponding to the thickness of the frame 19. On the upper surface of the frame support base 24, a plurality of suction ports 24a are provided at substantially equal intervals along a circumferential direction of the frame support base 24. Negative pressure is transmitted from a suction source (not illustrated) such as a vacuum pump to each suction port 24a.

Heat generators 24b as represented by cartridge heaters are provided inside the frame support base 24. Heat generated by the heat generators 24b is transmitted to the sheet 17 through the frame 19 and softens the sheet 17 at the time of thermocompression-bonding the sheet 17 to the frame 19.

With reference back to FIG. 3, a frame supply unit 30 exists on one side of the X-axis directions of the frame unit forming apparatus 20. The frame supply unit 30 includes a frame stocker 32 housing a plurality of frames 19 stacked in the Z-axis directions.

In the vicinity of the frame stocker 32, a first transfer apparatus 34 that holds one of the frames 19 under suction and transfers it is provided. The first transfer apparatus 34 includes a suction portion 34a for holding the frame 19 under suction and a moving block 34b movable along the X-axis directions.

The suction portion 34a has a bracket whose longitudinal portion is arranged along the Y-axis directions. The bracket has suction blocks at both end portions thereof. Each suction block has two suction pads arranged to sandwich the bracket in the X-axis directions.

The suction portion 34a is movable relative to the moving block 34b in the Z-axis directions by an actuator such as an air cylinder. The moving block 34b is moved along the X-axis directions by a movement mechanism (not illustrated). The movement mechanism (not illustrated) has, for example, a ball screw.

In this case, the moving block 34b is slidably fixed to a pair of guide rails, and a screw shaft is rotatably coupled to a nut portion fixed to the moving block 34b. Further, a motor such as a servomotor is coupled to one end portion of the screw shaft.

After the suction portion 34a disposed directly above the frame stocker 32 holds the frame 19 under suction with negative pressure, the moving block 34b is moved along one of the X-axis directions until the frame 19 reaches a position directly above the frame support base 24 (refer to FIG. 4A).

By combination of the movement of the moving block 34b in the X-axis directions and the movement of the suction portion 34a in the Z-axis directions, one frame 19 is moved from the frame stocker 32 to the frame support base 24 and placed thereon. After the frame 19 is held under suction on the frame support base 24, the sheet 17 is attached to the frame 19.

FIG. 4A is a side view illustrating, partially in cross section, how the sheet 17 is attached to the frame 19 in the frame unit forming apparatus 20. It is to be noted that the sheet support base 22 and the frame support base 24 illustrated in FIG. 4A are omitted from the illustration of FIG. 3.

On the rear side of the sheet support base 22, a roll body 17a into which the sheet 17 to be used has been wound is provided, and between the roll body 17a and the sheet support base 22 in the Y-axis directions, a pair of feed rollers 26a for feeding the sheet 17 from the roll body 17a are provided.

The pair of feed rollers 26a are supplied with power from a motor (not illustrated) and feed the sheet 17 sandwiched therebetween forward (i.e., to the other side of the Y-axis directions). On the side opposite to the pair of feed rollers 26a across the sheet support base 22 in the Y-axis directions, a pair of feed rollers 26b for feeding the sheet 17 are further provided.

The pair of feed rollers 26b are supplied with power from a motor (not illustrated) and feed the sheet 17 sandwiched therebetween forward in a manner synchronized with the feeding by the pair of feed rollers 26a. It is to be noted that the pairs of feed rollers 26a and 26b are omitted from the illustration of FIG. 3.

The sheet 17 fed by the pair of feed rollers 26b is wound up around a rotation axis 26c. The rotation axis 26c is also supplied with power from a motor (not illustrated) in synchronization with the pair of feed rollers 26a and the pair of feed rollers 26b.

A cutting unit 28 is provided above the sheet support base 22. The cutting unit 28 is movable along the Z-axis directions between a retracted position (refer to FIG. 4A) and a cut-in position (refer to FIG. 4B) by a Z-axis direction movement mechanism (not illustrated).

The cutting unit 28 has a columnar rotation axis 28a. The rotation axis 28a is supplied with power from a motor (not illustrated). A proximal end portion of an arm portion 28b is fixed to a lower end portion of the rotation axis 28a, and a cutting edge 28c is fixed to a distal end portion of the arm portion 28b such that the cutting edge 28c protrudes downward from the arm portion 28b.

A columnar pressure roller 29 is provided above the sheet support base 22 and in the vicinity of the cutting unit 28. The pressure roller 29 is movable along the Z-axis directions between a retracted position (an upper position in FIG. 4A) and a pressing position (a lower position in FIG. 4A) by a Z-axis direction movement mechanism (not illustrated).

The pressure roller 29 is movable along the Z-axis directions and also movable along the Y-axis directions. The length of the pressure roller 29 in its longitudinal direction is larger than the outer diameter of the frame 19. The pressure roller 29 is movable along the Y-axis directions while rotating and pressing the sheet 17 against the frame 19.

As illustrated in FIGS. 4A-4C, in the frame unit forming apparatus 20, the frame unit 21 is formed by thermocompression-bonding the sheet 17 to the frame 19. At the time of forming the frame unit 21, the first transfer apparatus 34 holding the frame 19 under suction enters the space between the sheet 17 and the frame support base 24 and places the frame 19 on the frame support base 24.

Then, as illustrated in FIG. 4A, one surface of the frame 19 is held under suction on the frame support base 24. Thereafter, the pressure roller 29 is lowered at a first position P_{A} in the Y-axis directions, and the sheet 17 disposed above the sheet support base 22 and the frame support base 24 is pressed by the pressure roller 29. The first position P_{A} is located between an inner circumferential edge and an outer circumferential edge of the frame 19 in the Y-axis directions.

At the time of thermocompression bonding, the frame 19 is heated to reach a temperature corresponding to a softening point of the sheet 17 by the heat from the heat generators 24b. In the state in which the pressure roller 29 keeps pressing the sheet 17, the pressure roller 29 is moved to a second position P_{B} in one of the Y-axis directions while rotating. Consequently, the sheet 17 is thermocompression-bonded to the frame 19.

The second position P_{B} is also located between the inner circumferential edge and the outer circumferential edge of the frame 19 in the Y-axis directions. For example, the distance from the center of the opening 19a to the first position P_{A} is the same as the distance from the center of the opening 19a to the second position P_{B}.

Then, after the pressure roller 29 is retracted, a lower end of the cutting edge 28c is made to cut in the sheet 17, and the arm portion 28b is rotated, so that the sheet 17 is cut out in a circular shape along the opening 19a of the frame 19. The frame unit 21 is formed in this manner.

FIG. 4B is a side view illustrating, partially in cross section, how the sheet 17 is cut out by the cutting unit 28, and FIG. 4C is a sectional view of the frame unit 21. While the sheet 17 is attached (i.e., fixed) to the frame 19 by thermocompression bonding in the present embodiment, the sheet 17 may have an adhesive layer including an adhesive in an annular area to be brought into contact with the frame 19.

After the sheet 17 is cut out, the cutting unit 28 is retracted upward to a position higher than the pairs of feed rollers 26a and 26b, and the used part of the sheet 17 is wound up around the rotation axis 26c until an unused part of the sheet 17 covers the whole of the sheet support base 22 and the frame support base 24.

The frame unit 21 is transferred from the frame unit forming apparatus 20 to the sheet fixing apparatus 10 by a second transfer apparatus 44 (refer to FIG. 3). As illustrated in FIG. 3, the second transfer apparatus 44 is provided in the vicinity of the sheet fixing apparatus 10 and the frame unit forming apparatus 20.

As with the first transfer apparatus 34, the second transfer apparatus 44 includes a suction portion 44a for holding the frame 19 under suction and a moving block 44b movable along the Y-axis directions.

The suction portion 44a has a bracket whose longitudinal portion is arranged along the X-axis directions. The bracket has suction blocks at both end portions thereof. Each suction block has two suction pads arranged to sandwich the bracket in the Y-axis directions. Further, the suction portion 44a is movable relative to the moving block 44b in the Z-axis directions.

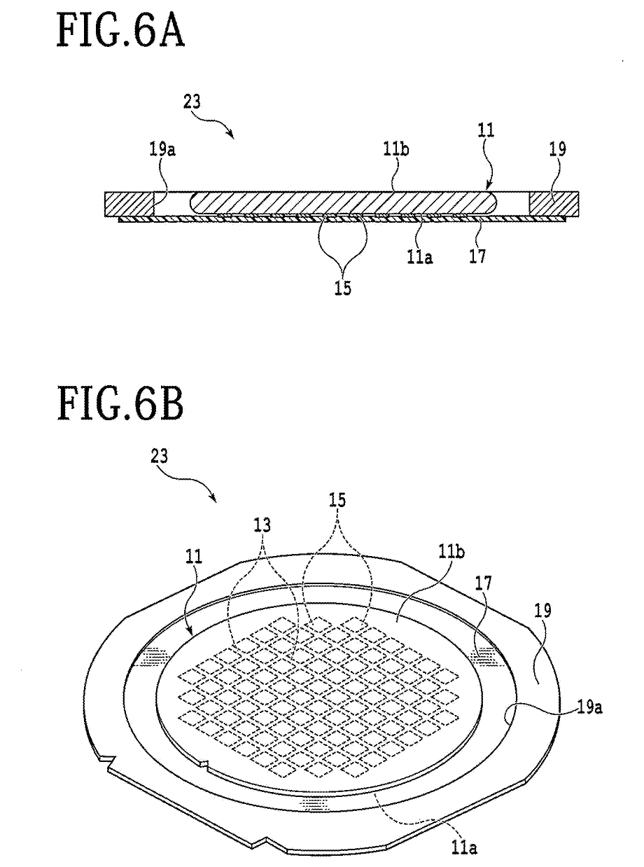

In the chamber 16 of the sheet fixing apparatus 10, as described above, the sheet 17 is fixed to the front surface 11a of the workpiece 11 to form a workpiece unit (i.e., adherend unit) 23 (refer to FIGS. 6A and 6B).

Thereafter, a third transfer apparatus 46 disposed in front of the frame stocker 32 transfers the workpiece unit 23 to the pressing apparatus 50 (refer to FIG. 3). As with the first transfer apparatus 34, the third transfer apparatus 46 includes a suction portion 46a for holding the frame 19 under suction and a moving block 46b movable along the X-axis directions.

The suction portion 46a has a bracket whose longitudinal portion is arranged along the Y-axis directions. The bracket has suction blocks at both end portions thereof. Each suction block has two suction pads arranged to sandwich the bracket.

The suction portion 46a is movable relative to the moving block 46b in the Z-axis directions. Further, the bracket of the suction portion 46a is rotatable about a rotation axis extending in parallel to the Y-axis directions by a motor (not illustrated).

The suction portion 46a enters a space below the workpiece unit 23 elevated by the suction portion 44a of the second transfer apparatus 44, supports the frame 19 from below, and holds the frame 19 under suction. After that, the suction portion 44a of the second transfer apparatus 44 cancels the suction holding of the frame 19.

Then, the suction portion 46a of the third transfer apparatus 46 turns the frame 19 upside down while holding the frame 19 under suction, so that the workpiece unit 23 is inverted such that the back surface 11b is exposed upward. The workpiece unit 23 is then placed on a second chuck table (i.e., table) 52 (refer to FIG. 7) of the pressing apparatus 50.

As illustrated in FIG. 7, the pressing apparatus 50 has the second chuck table 52 in a disk shaped. The second chuck table 52 is larger in diameter than the first chuck table 12 and supports the entire workpiece unit 23 such that the back surface 11b of the workpiece 11 is exposed.

The second chuck table 52 has a disk-shaped frame body made of metal such as stainless steel. At a radially central portion of the frame body, a disk-shaped recessed portion is provided concentrically, and in the recessed portion, a disk-shaped porous plate made of porous ceramic is fixed.

Upper surfaces of the frame body and the porous plate are substantially flush with each other and constitute a holding surface 52a that is substantially flat. Negative pressure is transmitted from a suction source (not illustrated) such as a vacuum pump to the upper surface of the porous plate. The workpiece unit 23 placed on the holding surface 52a is held under suction on the holding surface 52a.

It is to be noted that the second chuck table 52 is not limited to the one using negative pressure, either, and may be an electrostatic chuck that uses electrostatic force or the like to suck the workpiece unit 23.

Heat generators 52b as represented by cartridge heaters are provided in the frame body of the second chuck table 52. Heat generated by the heat generators 52b is transmitted from the holding surface 52a to the sheet 17 and softens the sheet 17 at the time of pressing the workpiece 11 against the sheet 17.

In addition, the frame body of the second chuck table 52 has a plurality of (four, for example) through holes (not illustrated), each of the through holes having one end exposed on the holding surface 52a. Each through hole is provided with a push-up pin (not illustrated) movable along the Z-axis directions.

The push-up pins are normally housed in the respective through holes. When the workpiece unit 23 is raised after predetermined processing in the pressing apparatus 50 ends, upper end portions of the push-up pins protrude upward to a position higher than the holding surface 52a. As a result, the workpiece unit 23 is pushed up by the plurality of push-up pins.

It is to be noted that the second chuck table 52 is movable in a predetermined range in the Y-axis directions by an actuator (not illustrated) such as a ball screw including a screw shaft coupled to a motor, or an air cylinder.

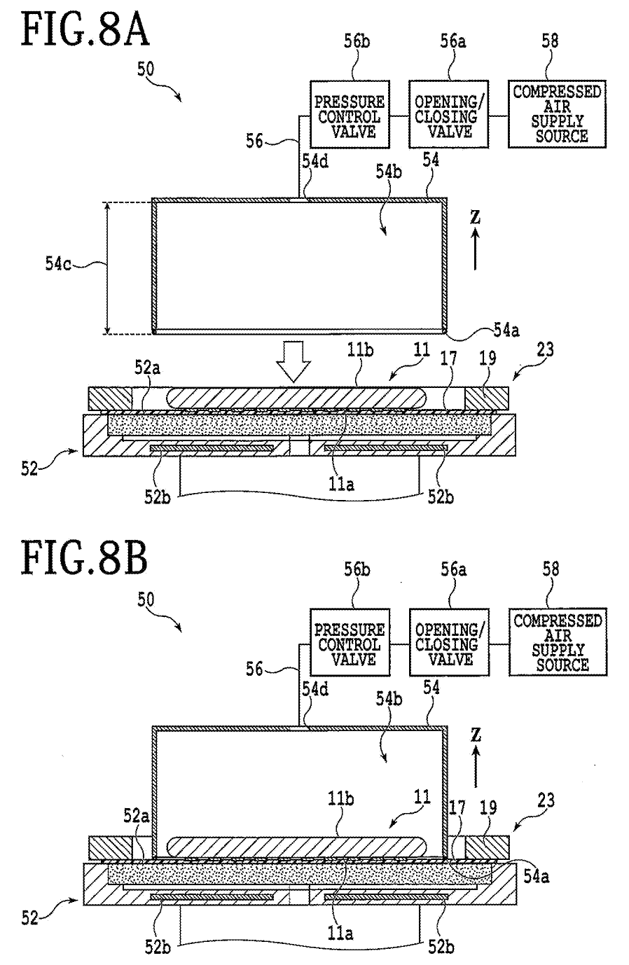

On the upper side of the second chuck table 52, a topped cylindrical chamber (i.e., cover member) 54 made of metal such as stainless steel is provided (refer to FIG. 8A). As illustrated in FIG. 8A, at a bottom portion of the chamber 54, a rubber-made or resin-made seal ring 54a is provided along a circumferential direction of the chamber 54.

The diameter of the chamber 54 in the present embodiment is larger than the outer diameter of the workpiece 11 but smaller than the diameter of the opening 19a of the frame 19. Thus, the chamber 54 can cover at least the workpiece 11 and a central portion of the sheet 17 in the workpiece unit 23. It is to be noted that the chamber 54 is indicated by a broken line in FIG. 3.

The chamber 54 is provided with a movement mechanism (not illustrated) that moves the chamber 54 along the Z-axis directions. The movement mechanism has an actuator (a ball screw including a motor, a screw shaft, and the like, or an air cylinder, for example). When the chamber 54 is lowered by the movement mechanism, the seal ring 54a is brought into contact with the sheet 17 (or the frame 19).

In this manner, an internal space 54b of the chamber 54 becomes a space enclosed by the sheet 17 (or the frame 19). At this time, airtightness between the chamber 54 and the sheet 17 (or the frame 19) is secured by the seal ring 54a.

It is to be noted that the diameter of the chamber 54 may be larger than the diameter of the opening 19a of the frame 19 but smaller than the outer diameter of the frame 19. In this case, when the chamber 54 is lowered toward the holding surface 52a, the seal ring 54a is brought into contact with an upper surface of the frame 19.

Thus, the diameter of the chamber 54 may suitably be set according to the size of the workpiece 11 or the frame 19. The height 54c specifying the internal space 54b of the chamber 54 is specified, for example, by the distance from a lower end of the seal ring 54a to an inner surface of a top plate in the Z-axis directions.

In a case in which the workpiece 11 has a diameter of 200 mm, for example, an inner diameter of the internal space 54b is 204 mm, and the height 54c of the internal space 54b of the chamber 54 is 3 mm. However, the above-described size of the chamber 54 is merely an example.

The chamber 54 has a small-diameter opening 54d at a top central portion thereof. One end portion of a pipe portion 56 is fixed to the opening 54d. To another end portion of the pipe portion 56, a compressed air supply source 58 for supplying compressed air to the chamber 54 is provided.

The compressed air supply source 58 is, for example, installed in a building such as a factory and is provided separate from the attachment apparatus 2. The compressed air supply source 58 includes a compressor for taking in air from the atmosphere and compressing the air, a tank for storing compressed air, and a filter for removing dust and the like, for example (all of which are not illustrated).

Between the one end portion and the other end portion of the pipe portion 56, an opening/closing valve 56a and a pressure control valve 56b which are opened and closed by a controller 62 are provided. The opening/closing valve 56a is a solenoid valve for opening and closing a flow channel of the pipe portion 56, and the degree of opening of the valve is adjusted to 0% or 100%.

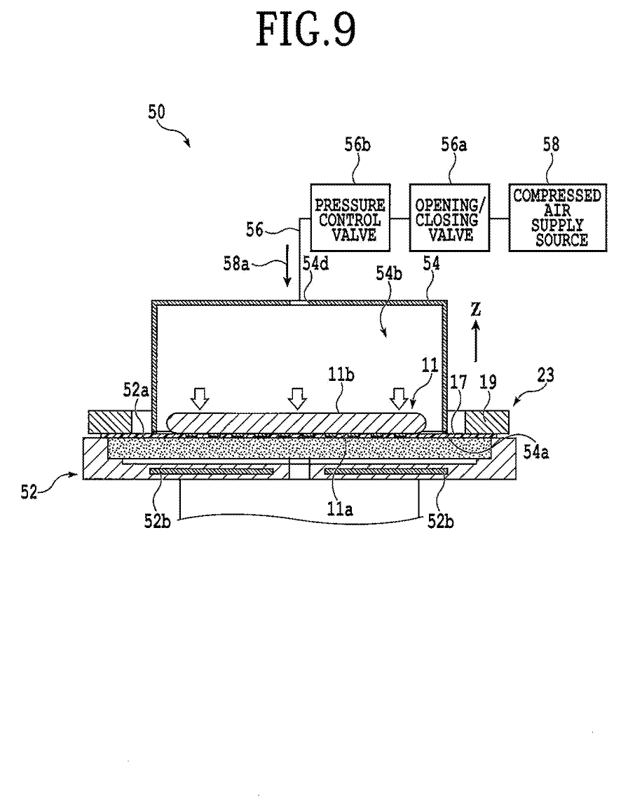

The pressure control valve 56b is a solenoid valve for adjusting the pressure of air (gas) 58a (refer to FIG. 9) flowing through the flow channel of the pipe portion 56 to a predetermined value. When the opening/closing valve 56a and the pressure control valve 56b are opened, the air 58a is supplied to the internal space 54b of the chamber 54 at the predetermined pressure value.

The internal space 54b of the chamber 54 is supplied with the air 58a of an ambient temperature (i.e., 20° C. ± 5° C.) at a pressure of 0.1 MPa to 1.0 MPa, more preferably, at a pressure of 0.3 MPa to 0.5 MPa, for example.

Since the internal space 54b of the chamber 54 is quite small, it is filled with the air 58a only by supplying the air 58a of the ambient temperature at the predetermined pressure from the compressed air supply source 58 for approximately one second. After the internal space 54b of the chamber 54 is supplied with the air 58a, the opening/closing valve 56a and the pressure control valve 56b are closed.

By making the pressure in the internal space 54b of the chamber 54 higher than the pressure in a space outside the chamber 54 in this manner, the workpiece 11 is pressed against the sheet 17, so that the sheet 17 is fixed to the front surface 11a of the workpiece 11.

For example, at the time of pressing the workpiece 11 against the sheet 17, a state in which the sheet 17 is heated to reach its softening point by the second chuck table 52 and the internal space 54b of the chamber 54 is filled with the air 58a is maintained for a predetermined period of time (120 s to 180 s, for example).

In the present embodiment, the workpiece 11 is pressed against the sheet 17, and hence, the minute gap 11c existing between the front surface 11a of the workpiece 11 and the sheet 17 can be reduced.

It is to be noted that the heating of the sheet 17 to reach the softening point is not necessary when the workpiece 11 is pressed against the sheet 17 in the internal space 54b of the chamber 54. Without heating the sheet 17, it is possible to achieve to a certain extent the effect of reducing the minute gap 11c existing between the front surface 11a of the workpiece 11 and the sheet 17.

However, if the sheet 17 is heated to reach the softening point, the surface of the sheet 17 in contact with the holding surface 52a (i.e., the surface of the sheet 17 on the side opposite to the surface in contact with the workpiece 11) can be made substantially flat following the holding surface 52a, which is advantageous.

Moreover, if the surface of the sheet 17 in contact with the holding surface 52a can be made substantially flat following the holding surface 52a through such heating and pressing, this is also advantageous in that cutting chips are not generated at the time of flattening unlike a related-art technology in which the sheet 17 or a photo-curing resin is flattened by cutting with a cutting tool.

Description will now return to FIG. 3. In the vicinity of the pressing apparatus 50, a pair of guide rails 60a and a pusher 60b are provided. The pair of guide rails 60a are moved closer to each other or away from each other along the X-axis directions by an unillustrated actuator.

The pusher 60b is movable along the Y-axis directions by an unillustrated actuator. The pusher 60b pushes the workpiece unit 23 elevated from the holding surface 52a by the plurality of push-up pins, toward the pair of guide rails 60a, and transfers the workpiece unit 23 to a cassette 6c disposed in a cassette placement area 4c.

The attachment apparatus 2 includes the controller 62 that controls operation of the components. The controller 62 is configured by, for example, a computer including a processor 62a typified by a central processing unit (CPU) and a memory 62b.

The memory 62b includes a main storage unit such as a dynamic random access memory (DRAM) and an auxiliary storage unit such as a flash memory. The auxiliary storage unit stores therein software including a predetermined program, and the processor 62a and the like are operated according to the software to implement functions of the controller 62.

Next, the respective steps of FIG. 1 are described with reference to FIGS. 5A-9. FIG. 5A is a side view of the sheet fixing apparatus 10, partially illustrated in cross section, and FIG. 5B is a side view illustrating, partially in cross section, how the workpiece unit 23 is formed (S10: sheet fixing step).

At S10, first, as illustrated in FIG. 5A, the back surface 11b of the workpiece 11 is held under suction on the first chuck table 12 such that the front surface 11a is exposed, and then, the frame 19 of the frame unit 21 is held under suction on the frame support base 14.

In this state, the chamber 16 is lowered, so that the chamber 16 defines an enclosed space, and the workpiece 11 and the frame unit 21 are disposed in the enclosed space. Thereafter, the internal space of the chamber 16 is evacuated to a vacuum. This can reduce the possibility that air bubbles are caught between the sheet 17 and the front surface 11a.

After the internal space of the chamber 16 is evacuated to a vacuum, the heat generators 12b are energized to heat the first chuck table 12, thereby heating the sheet 17 (i.e., the base layer of the thermocompression bonding sheet) to reach the temperature corresponding to the softening point.

The frame support base 14 is then lowered relative to the first chuck table 12, so that the upper surface of the frame 19 is positioned in height between the front surface 11a of the workpiece 11 and the holding surface 12a. Thereafter, the sheet 17 is pressed against the workpiece 11 by the pressure roller 18.

In this state, the pressure roller 18 is moved in one of the Y-axis directions while rotating, so that the sheet 17 is thermocompression-bonded to the front surface 11a of the workpiece 11. This is how the sheet 17 is fixed to the front surface 11a of the workpiece 11.

Since the sheet 17 is already fixed to the frame 19 in the present embodiment, fixing of the sheet 17 to both the frame 19 and the front surface 11a of the workpiece 11 is completed at S10. That is, in the state in which the workpiece 11 is disposed in the opening 19a of the frame 19, the workpiece unit 23 including the workpiece 11, the sheet 17, and the frame 19 integrated with one another is formed.

FIG. 6A is a side view of the workpiece unit 23 formed at S10, partially illustrated in cross section, and FIG. 6B is a perspective view of the workpiece unit 23. After the workpiece unit 23 is formed, the workpiece unit 23 is elevated by the second transfer apparatus 44.

Then, the third transfer apparatus 46 receives the workpiece unit 23 from the second transfer apparatus 44, turns the workpiece unit 23 upside down, and then transfers the workpiece unit 23 to the second chuck table 52 such that the back surface 11b of the workpiece 11 is exposed upward. The workpiece unit 23 is thus supported on the second chuck table 52.

FIG. 7 is a side view illustrating, partially in cross section, that the workpiece unit 23 is supported on the second chuck table 52 (S20: supporting step). At S20 in the present embodiment, the holding surface 52a supports and holds the workpiece unit 23 under suction.

It is to be noted that, after S20 but before S40, there is the minute gap 11c (refer to a broken line circle in FIG. 7) formed due to the irregularities of the front surface 11a. If the workpiece 11 is divided in units of device with the minute gap 11c formed, there is the possibility that the minute gap 11c causes cracks, chipping, and the like, thereby damaging device chips. Therefore, in the present embodiment, the pressing apparatus 50 is used to reduce the minute gap 11c. FIG. 8A is a side view of the pressing apparatus 50, partially illustrated in cross section.

After S20, in the present embodiment, the chamber 54 is lowered to bring the seal ring 54a positioned at the lower end portion of the chamber 54 into contact with the sheet 17, and as a result, at least the workpiece 11 is covered with the chamber 54 (S30: covering step). FIG. 8B is a side view illustrating, partially in cross section, that at least the workpiece 11 is covered with the chamber 54 (S30).

It is to be noted that S20 may be performed after S30. In the case of performing S20 after S30, in the state in which the enclosed space defined by the chamber 54 and the sheet 17 is formed, the chamber 54 and the workpiece unit 23 are lowered, and the workpiece unit 23 is then held on the holding surface 52a under suction. That is, it is sufficient if S30 is performed after S10.

After S20 and S30, the pressure in the internal space 54b of the chamber 54 is made higher than the pressure in the space outside the chamber 54, thereby pressing the workpiece 11 against the sheet 17 (S40: pressure controlling step). FIG. 9 is a side view illustrating, partially in cross section, how the pressure in the internal space 54b of the chamber 54 is made higher than the pressure in the space outside the chamber 54.

It is to be noted that the pressure in the space outside the chamber 54 in the present embodiment represents the pressure in a space that is in contact with an outer surface of the chamber 54 and is located outside the space enclosed by the chamber 54 and the workpiece unit 23. Needless to say, before making the pressure in the internal space 54b higher, the pressure in the internal space 54b is the same as the pressure in the space outside the chamber 54.

Since the sheet 17 in the present embodiment is a polyethylene sheet, prior to performing S40, the heat generators 52b are energized to heat the second chuck table 52 and cause the holding surface 52a to reach 140° C., and the sheet 17 held on the holding surface 52a under suction is thus heated to reach the temperature corresponding to the softening point.

Hence, the second chuck table 52 may be started to be heated at S20 or S30. It is to be noted that the holding surface 52a may be heated to reach the temperature corresponding to the softening point of the sheet 17, when the air 58a is supplied to the internal space 54b of the chamber 54 (i.e., when S40 is started).

In the present embodiment, in the state in which the holding surface 52a has been heated to reach the temperature corresponding to the softening point of the sheet 17, the air 58a is supplied to the internal space 54b of the chamber 54, thereby making the pressure in the internal space 54b of the chamber 54 higher than the pressure in the space outside the chamber 54. The workpiece 11 is thus pressed against the sheet 17 by the air 58a.

The internal space 54b of the chamber 54 is, for example, supplied with the air 58a of the ambient temperature at the pressure of 0.1 MPa to 1.0 MPa, more preferably, at the pressure of 0.3 MPa to 0.5 MPa, for approximately one second. The internal space 54b of the chamber 54 is thus filled with the air 58a.

Then, the state in which the sheet 17 has been heated to reach the softening point and the internal space 54b of the chamber 54 is filled with the air 58a is maintained for the predetermined period of time (120 s to 180 s, for example). In this manner, the minute gap 11c (refer to the broken line circle in FIG. 7) between the front surface 11a of the workpiece 11 and the sheet 17 is reduced.

Incidentally, the gas used to press the workpiece 11 in the chamber 54 of the pressing apparatus 50 is not limited to the air 58a described above. Besides the air 58a, for example, inert gas such as argon (Ar) gas, carbon dioxide (CO₂) gas, or nitrogen (N₂) gas may alternatively be used.

Further, instead of the gas, liquid such as pure water may press the workpiece 11 in the chamber 54. That is, in the chamber 54, fluid which is gas or liquid may be used to press the workpiece 11 against the sheet 17. By using liquid, it is possible to press the workpiece 11 at a pressure equivalent to that in the case of gas even with a relatively simple pump.

In addition, since liquid generally has a specific heat larger than that of gas, if heated liquid is used, it is possible to not only press the workpiece 11 against the sheet 17 but also heat the workpiece 11 and the sheet 17 with the heat transmitted through the liquid.

It is to be noted that, while the chamber 54 which is a typical container made of stainless steel or the like is used in the embodiment described above, a deformable bag (i.e., cover member) made of a flexible material such as a base fabric for an air bag may instead be used for the pressing apparatus 50.

### Second Embodiment

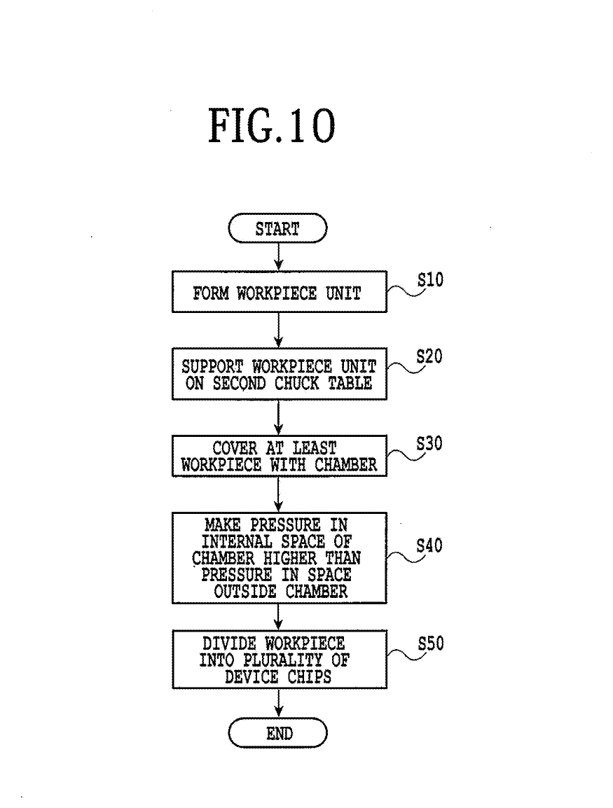

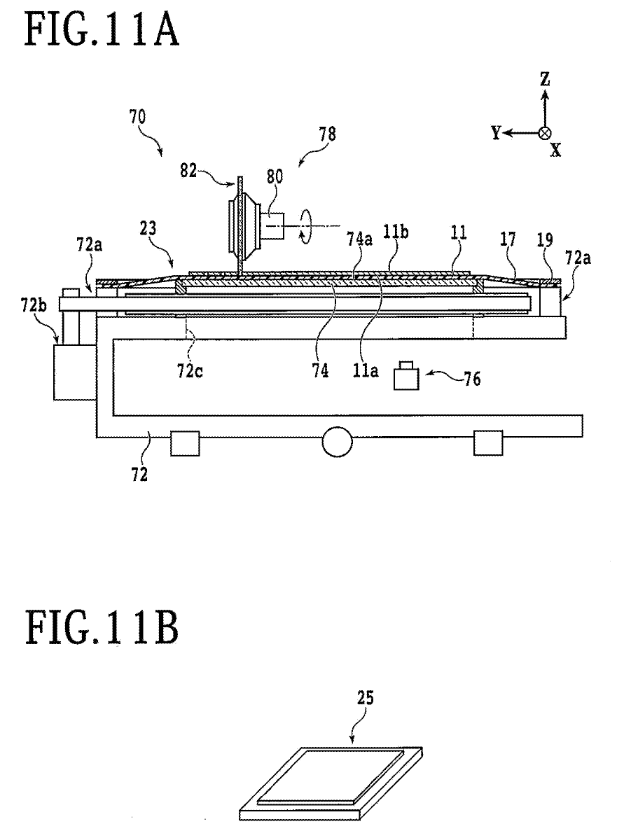

A second embodiment will next be described with reference to FIGS. 10, 11A, and 11B. FIG. 10 is a flowchart of a method for manufacturing device chips (i.e., chips) 25 (refer to FIG. 11B) according to the second embodiment.

In the second embodiment, after the sheet 17 is fixed to the front surface 11a of the workpiece 11 and the minute gap 11c between the front surface 11a and the sheet 17 is reduced, a processing apparatus is used to divide the workpiece 11 into the plurality of device chips 25.

Since steps S10-S40 in the second embodiment are the same as those in the first embodiment, redundant description is omitted. First described with reference to FIG. 11A is a cutting apparatus 70 used to divide the workpiece 11 into the plurality of device chips 25 (S50: dividing step).

The X-axis directions (processing-feed directions), the Y-axis directions (indexing-feed directions), and the Z-axis directions (cutting-feed directions) indicated in FIG. 11A are orthogonal to one another. The cutting apparatus 70 in the present embodiment has a disk-shaped chuck table 72. The chuck table 72 has a disk-shaped holding plate 74 having a substantially transparent area through which visible light can pass.

The holding plate 74 is made of a transparent member such as quartz glass, borosilicate glass, or soda glass. The holding plate 74 has an upper surface formed with a plurality of openings for transmitting negative pressure, and the upper surface of the holding plate 74 functions as a holding surface 74a for holding the workpiece 11 through the sheet 17 under suction.

The holding plate 74 is rotatable when supplied with power transmitted from a motor 72b provided to a side portion of the chuck table 72. In addition, around the holding plate 74, a plurality of frame support portions 72a are provided at substantially equal intervals along a circumferential direction of the holding plate 74. Each frame support portion 72a supports the frame 19 and holds the frame 19 under suction with negative pressure.

Below the holding plate 74, an imaging unit 76 that images the workpiece 11 with visible light is provided. The imaging unit 76 has a light source including a light emitting diode (LED) and a solid-state image sensor for performing photoelectric conversion.

The imaging unit 76 irradiates the front surface 11a of the workpiece 11 with visible light from the light source through an opening 72c defined in a top plate of the chuck table 72, the holding plate 74, and the sheet 17, and images the front surface 11a by having the image sensor perform a photoelectric conversion on light reflected from the front surface 11a.

A cutting unit 78 is provided above the holding plate 74. The cutting unit 78 has a columnar spindle 80 whose longitudinal direction is set substantially in parallel to the Y-axis directions. Part of the spindle 80 is rotatably housed in a spindle housing (not illustrated).

The spindle 80 is rotated at high speed by a motor (not illustrated) provided in the spindle housing. A tip end portion of the spindle 80 protrudes outward from the spindle housing. To the tip end portion of the spindle 80, a cutting blade 82 having an annular cutting edge is mounted.

The cutting blade 82 is, for example, what is generally called a hub blade having a cutting edge fixed to one surface of an annular base, but may alternatively be what is generally called a hub-less blade (i.e., washer type) having a cutting edge only and not having a base. At a tip end portion of the spindle housing, a nozzle unit (not illustrated) for supplying cutting water such as pure water to the cutting edge of the cutting blade 82 is provided.

FIG. 11A is a side view illustrating, partially in cross section, how the workpiece 11 is divided into the plurality of device chips 25. At S50, after the imaging unit 76 images the planned dividing lines 13, orientation of the holding plate 74 is adjusted such that the planned dividing lines 13 are set substantially in parallel to the X-axis directions. The spindle 80 is then rotated at high speed, and a lower end of the cutting blade 82 is positioned between the holding surface 74a and the front surface 11a in the Z-axis directions.

Thereafter, while the cutting water is being supplied from the nozzle unit at a predetermined flow rate, the chuck table 72 is moved in one of the X-axis directions in such a manner that the lower end of the cutting blade 82 traces one of the planned dividing lines 13. After the workpiece 11 is cut along the one planned dividing line 13, the cutting unit 78 is moved (i.e., indexing-fed) in one of the Y-axis directions by a predetermined amount.

Then, similar cutting is performed on another planned dividing line 13 that is adjacent in the Y-axis directions to the planned dividing line 13 along which the workpiece 11 has just been cut. After the workpiece 11 has been cut along all the planned dividing lines 13 extending along the X-axis directions, the holding plate 74 is rotated by approximately 90 degrees. Then, the workpiece 11 is similarly cut along all the planned dividing lines 13 extending along the X-axis directions.

Consequently, the workpiece 11 fixed to the sheet 17 is divided into the plurality of device chips 25. FIG. 11B is a perspective view of one device chip 25. Since the minute gap 11c between the front surface 11a and the sheet 17 has been reduced in the second embodiment, it is possible to suppress occurrence of cracks, chipping, and the like that would be caused by the minute gap 11c.

It is to be noted that the processing apparatus that performs S50 is not limited to the cutting apparatus 70. A laser processing apparatus (not illustrated) may be used instead of the cutting apparatus 70. The laser processing apparatus has the chuck table 72 described above and a laser beam irradiation unit. The laser beam irradiation unit includes a laser oscillator and a head portion. The laser oscillator has, for example, a crystal such as Nd:YAG as a laser medium.

When the crystal is irradiated with excitation light emitted from a light source such as a laser diode, the laser oscillator emits a pulsed laser beam having a wavelength (1064 nm, for example) that mostly passes through the workpiece 11 (silicon wafer, for example).

The laser beam irradiation unit may use a nonlinear optical crystal such as cesium lithium borate (CLBO) to convert a pulsed laser beam emitted from the laser oscillator into a higher harmonic laser beam. A laser beam that is the fourth harmonic (wavelength 266 nm) of the wavelength 1064 nm is mostly absorbed by the workpiece 11 (silicon wafer, for example).

The pulsed laser beam is applied to the workpiece 11 held on the holding surface 74a under suction, in a state in which the advancing direction thereof has been changed by a mirror provided in the head portion and then the pulsed laser beam has been focused by a condenser lens provided in the head portion.

In the case in which the laser beam has a wavelength mostly absorbable by the workpiece 11, a focal point of the laser beam and the chuck table 72 are moved relative to each other in such a manner that the focal point positioned at the back surface 11b traces the relevant planned dividing line 13.

Through the relative movement between the focal point and the workpiece 11, ablation processing is performed along a movement locus of the focal point, so that a laser-processed groove for use in cutting the workpiece 11 is formed. By forming a laser-processed groove along each planned dividing line 13, the workpiece 11 is divided in units of device chip 25.

Further, in the case in which the laser beam has a wavelength mostly transmittable through the workpiece 11, the focal point of the laser beam and the chuck table 72 are moved relative to each other in such a manner that the focal point positioned between the back surface 11b and the front surface 11a traces the relevant planned dividing line 13. As a result, a relatively fragile modified region is formed along a moving path of the focal point.

After the modified region is formed along each planned dividing line 13, external force is applied to the workpiece 11, so that the workpiece 11 is divided into the plurality of device chips 25. Application of the external force is performed by, for example, grinding of the back surface 11b, application of ultrasonic vibrations to the workpiece 11, or radial expansion of the sheet 17.

Incidentally, at S50, it is also possible to use a plasma processing apparatus (not illustrated) instead of the cutting apparatus. In the case of performing S50 by the plasma processing apparatus, the workpiece 11 is first held under suction on an electrostatic chuck, and then, for example, the Bosch process is performed to cut the workpiece 11 along each planned dividing line 13 by plasma processing (i.e., plasma dicing is performed).

Moreover, the structures, methods, and the like according to the above embodiments may appropriately be modified and implemented without departing from the scope of the object of the present invention. For example, while the sheet 17 and the frame 19 are integrated with the workpiece 11 in the embodiments described above, it is also possible to omit the frame 19 and integrate the sheet 17 and the workpiece 11 with each other.

In the case in which the back surface 11b of the workpiece 11 is not formed with the metal film and the semiconductor wafer is exposed, for example, the sheet 17 may be fixed to the front surface 11a for the purpose of grinding the back surface 11b to thin the workpiece 11. In this case as well, the above-described steps S10 to S40 are applicable.

Further, while the attachment apparatus 2 has two different chuck tables (i.e., the first chuck table 12 and the second chuck table 52) in the case described above, the attachment apparatus 2 may instead have only one chuck table (the first chuck table 12 or the second chuck table 52).

In the case in which the attachment apparatus 2 has the second chuck table 52 only, for example, the second chuck table 52 is movable in the X-axis directions and the Y-axis directions by a movement mechanism having a ball screw including a motor, a screw shaft, and the like, and is used in a shared manner by the sheet fixing apparatus 10 and the pressing apparatus 50.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A sheet fixing method for fixing a sheet to one surface of an adherend, the method comprising:
forming an adherend unit by fixing the sheet to the one surface of the adherend;
after forming the adherend unit, supporting the adherend unit on a table such that another surface of the adherend on a side opposite to the one surface is exposed;
after forming the adherend unit, covering at least the adherend in the adherend unit with a cover member; and
after supporting the adherend unit on the table and covering the adherend with the cover member, making a pressure in an internal space of the cover member that covers the adherend higher than a pressure in a space outside the cover member.

2. The sheet fixing method according to claim 1, wherein, in making the pressure in the internal space of the cover member higher than the pressure in the space outside the cover member, gas is supplied to the internal space of the cover member, and the gas presses the adherend against the sheet.

3. The sheet fixing method according to claim 1, wherein
the sheet is a thermocompression bonding sheet having a base layer and not having an adhesive layer made of an adhesive, and,
in forming the adherend unit, the base layer is heated to thermocompression-bond the thermocompression bonding sheet to the one surface of the adherend.

4. The sheet fixing method according to claim 1, wherein, in making the pressure in the internal space of the cover member higher than the pressure in the space outside the cover member, the pressure in the internal space of the cover member is made higher than the pressure in the space outside the cover member in a state in which the sheet fixed to the adherend of the adherend unit is heated.

5. The sheet fixing method according to claim 4, wherein, in making the pressure in the internal space of the cover member higher than the pressure in the space outside the cover member, the pressure in the internal space of the cover member is made higher than the pressure in the space outside the cover member in a state in which the sheet is held on the table under suction.

6. The sheet fixing method according to claim 1, wherein, in forming the adherend unit, the adherend unit is formed by fixing the sheet to an annular frame having an opening at a radially central portion thereof and to the one surface of the adherend and then integrating the adherend, the frame, and the sheet with one another with the adherend disposed in the opening.

7. A chip manufacturing method for fixing a sheet to one surface of an adherend and then dividing the adherend into a plurality of chips, the method comprising:
forming an adherend unit by fixing the sheet to the one surface of the adherend;
after forming the adherend unit, supporting the adherend unit on a table such that another surface of the adherend on a side opposite to the one surface is exposed;
after forming the adherend unit, covering at least the adherend in the adherend unit with a cover member;
after supporting the adherend unit on the table and covering the adherend with the cover member, making a pressure in an internal space of the cover member that covers the adherend higher than a pressure in a space outside the cover member; and
after making the pressure in the internal space of the cover member higher than the pressure in the space outside the cover member, dividing the adherend fixed to the sheet into a plurality of chips.

8. A pressing apparatus that presses an adherend against a sheet to fix the sheet to one surface of the adherend, the apparatus comprising:
a table for supporting an adherend unit obtained by fixing the sheet to the one surface of the adherend, such that another surface of the adherend on a side opposite to the one surface is exposed; and
a cover member that is provided above the table and covers at least the adherend in the adherend unit supported on the table, wherein
the adherend is pressed against the sheet by making a pressure in an internal space of the cover member higher than a pressure in a space outside the cover member in a state in which the cover member covers at least the adherend.
